(19) United States
(12) Patent Application Publication
(10) Pub. No.: US 2010/0189897 A1
(43) Pub. Date: Jul. 29, 2010

(54) HIGH TEMPERATURE EVAPORATOR CELL HAVING PARALLEL-CONNECTED HEATING ZONES

(75) Inventors: Wolfgang Braun, Berlin (DE); Albrecht Fischer, Loechgau (DE); Tatsuro Watahiki, Berlin (DE)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignees: CREATEC FISCHER & CO. GMBH, Erligheim (DE); FORSCHUNGSVERBUND BERLIN E.V., Berlin (DE)

(21) Appl. No.: 12/670,120

(22) PCT Filed: Jul. 21, 2008
(86) PCT No.: PCT/EP08/05953

§ 371 Date: Mar. 5, 2010

(30) Foreign Application Priority Data
Jul. 27, 2007 (DE) 10 2007 035 166.8

(51) Int. Cl. C23C 16/52; C23C 16/44; H05B 3/02; H05B 1/02; C23C 16/00

(52) U.S. Cl. 427/248.1; 392/307; 219/494; 118/666; 118/726

(57) ABSTRACT

An evaporator cell (100), which is adapted for evaporating, in particular, a high-melting evaporant, includes a crucible (10) for receiving the evaporant, said crucible including a crucible bottom (11), a side wall (12) which extends in an axial direction of the crucible (10), and a crucible opening (13), and a heating device (20) with a heating resistor (21), which has a plurality of heating zones (21.1, 21.2), which are arranged on an outside surface of the crucible (10) and extend axially along the crucible (10), wherein the heating zones (21.1, 21.2) are equipped for multilateral resistance heating and/or electron beam heating of the crucible (10), and wherein the heating zones (21.1, 21.2) are constructed in such a manner that a heating current through the heating resistor (21), which is formed for example by a resistance sleeve, flows in parallel and in the same sense through all heating zones (21.1, 21.2). A method of operating the evaporator cell is also described.

The invention relates to an evaporator cell with the features of the preamble of claim 1, in particular an effusion evaporator cell for transforming an evaporant to the gas phase (evaporation, sublimation), and a method of evaporation of evaporant with said evaporator cell.

The evaporation of materials for the deposition of thin layers is a widely used method, e.g. in technical physics and in semiconductor technology. When using high-melting materials, which are only converted to the gas phase at extremely high temperatures (above e.g. 1800° C., in particular above 2000° C.), there are special requirements, in particular relating to temperature stability and setting of the evaporation rate during evaporation. Moreover, for example in the production of thin-film components for CMOS technology, there is interest in controllable and reproducible, non-reactive vapor deposition of insulator films, in which the evaporant has the desired stoichiometric composition of the insulator films.

DE 10 2005 025 935 A1 describes an evaporator cell that comprises a crucible for receiving evaporant and a heating resistor, which is arranged both for resistance heating and for electron beam heating of the crucible. The heating resistor comprises a heater coil, which surrounds the crucible on all sides, with heating elements, which extend axially along the crucible. The heater coil is secured with electrical insulators on a shielding, which surrounds the crucible. To avoid unwanted magnetic fields on applying an operating current to the heating resistor, the heating elements are aligned oppositely in pairs and are connected in series. For controlling the resistance heating and the electron beam heating, control circuits are provided, which are connected to a temperature sensor.

With the evaporator cell according to DE 10 2005 025 935 A1, stepless transition from resistance heating to electron beam heating is possible, so that the temperature of the evaporant can be set in a wide temperature range. For example, purification of the material is provided in a lower temperature region, and transformation of the material to the gas phase is provided in a higher temperature region.

The following problems can arise with the conventional evaporator cell. The electrical insulators for securing the heater coil can be damaged by operation at high temperatures. If an insulator fails, a short-circuit may occur, leading to failure of the whole evaporator cell. Furthermore, there may be variations of electrical resistance along the length of the heater coil. The variations can produce non-uniform heating of the evaporant in the crucible. The aforementioned problems occur in particular at high temperatures, for example in the range from 2200 to 2500° C. Moreover, an inhomogeneous heating effect may develop, as despite uniform energy supply, the crucible tends to heat up less strongly from the bottom towards the crucible opening.

Another disadvantage of the conventional evaporator cell arises from the fact that in order to improve trouble-free operation without the resistance heating and electron beam heating affecting each other, two control circuits are provided. This can be a disadvantage owing to the complexity of construction and increased costs. Finally, long-term operation of the existing evaporator cell has shown that the temperature sensor used for control can fail under the action of the high operating temperature. After a sensor fails, expensive dismantling of the evaporator cell may be necessary.

The objective of the invention is to provide an improved evaporator cell for transforming in particular high-melting materials to the gas phase, in particular an improved effusion cell, with which disadvantages of the conventional evaporator cell are overcome and which in particular permits reliable, long-term operation at high temperatures, e.g. above 1900° C. Another objective to be solved by the invention is to provide an improved method of evaporation in particular of high-melting materials, with which disadvantages of conventional techniques are overcome.

These objectives are solved by an evaporator cell and a method of evaporation with the features of the independent claims. Advantageous embodiments and applications of the invention can be seen from the dependent claims.

With respect to the device, the invention is based on the general technical teaching of providing an evaporator cell with a crucible and a heating resistor, which comprises a plurality of heating zones for resistance and/or electron beam heating of the crucible. In contrast to the conventional use of a heater coil with series-connected heating elements, the heating zones of the evaporator cell according to the invention have parallel electrical connection on an outside surface of the crucible. The heating zones are adapted to be connected electrically in parallel to connections of a power supply for resistance and electron beam heating. The crucible has an axial direction that corresponds to a connecting line between a crucible bottom and a crucible opening. The parallel connection extends in the axial direction of the crucible. When a heating voltage is admitted to the heating zones, a heating current flows in parallel and in the same direction through all heating zones.

Parallel connection of the heating zones offers a number of advantages. First, at each of the connections, e.g. at the crucible bottom or at the crucible opening, only one contact is required for connecting the heating zones to the power supply device. Securing of the heating device on the outside surface of the crucible is simplified. It can in particular be secured without the need for electrical insulators in regions of particularly high temperature, i.e. near the crucible opening. Moreover, possible variations of electrical resistance in the material of the heating zones are equalized by the parallel connection. This results in increased uniformity of crucible heating. Finally, the inventors found that unwanted magnetic fields can be avoided not only with the conventional heater coil, but also with the parallel connection of the heating zones, by providing zones in the evaporator cell with a current direction that is opposite to the current direction in the heating zones. This can be achieved for example with parts of a shielding device (see below) or an additional conductor.

With respect to the method, the invention is based on the general technical teaching of subjecting evaporant in a crucible of an evaporator cell to indirect heating with a group of parallel-connected heating zones arranged outside of the crucible, forming resistance heating of the crucible in a first temperature range and electron beam heating of the crucible in a second temperature range.

Preferably, the evaporant that is evaporated comprises a high-melting material. High-melting material is characterized by a melting point above 1500° C., in particular above 2000° C.

A particular advantage of the invention is that the evaporator cell has a simplified structure compared with the conventional evaporator cell and makes reliable long-term operation possible, without impairing the excellent properties of the evaporator cell, particularly with respect to temperature adjustment.

The evaporator cell according to the invention is preferably an effusion cell. It is suitable in particular for precise and reproducible deposition of layers of high-melting materials, e.g. in semiconductor technology. With the evaporator cell, temperatures are reached that are above 2000° C., e.g. above 2300° C., in particular up to almost 3000° C., e.g. up to 2900° C. Another advantage of the invention is that with one single heating device of the evaporator cell according to the invention, it is possible to set a temperature in a temperature range that extends from room temperature (or even lower) up to the aforementioned high temperatures.

The evaporator cell according to the invention has an extended field of application. It can for example be used for long-term operation together with a plurality of other evaporator cells in a coating installation, wherein the evaporator cells can be controlled without affecting one another and have low maintenance costs.

In the following, the material to be processed will be called the “evaporant” regardless of the actual function performed by the evaporator cell and regardless of the type of phase transition as evaporation or sublimation. Correspondingly, the transition to the gas phase will be called “evaporation” hereinafter, regardless of whether in the actual case there is evaporation from the melt or sublimation from the solid.

The parallel-connected heating zones for combined resistance heating and electron beam heating extend according to the invention on several sides of the crucible, so that advantageously the accuracy and reproducibility of temperature setting can be improved. The crucible typically comprises the crucible bottom and a side wall, which encloses an internal space of the crucible. According to preferred features, the crucible can be in the form of a cylinder, e.g. with a circular or elliptical base or in the form of a cone. Distribution of the heating zones on several sides of the crucible means that the heating zones (or heating resistor segments) are arranged distributed on the outside surface of the side wall. Particularly for the evaporation of larger amounts of evaporant, it is preferably provided that the crucible has an elongated shape. The characteristic size (e.g. the diameter) of the crucible bottom is less than the extension (e.g. height of the side walls). According to the invention, the heating zones extend along the longitudinal extension (axial direction) on the outside surface of the crucible.

According to a first embodiment of the invention, the heating zones comprise heating elements running axially along the crucible, separated from one another. The heating elements are connected in parallel between the terminals of the heating resistor, which are arranged with distances in axial directions. The use of heating elements that are arranged spaced apart of one another has the advantage that during operation of the evaporator cell it is possible to observe the crucible, e.g. for purposes of monitoring or for temperature measurement with optical means. Moreover, the heating elements make it possible to provide a relatively high resistance value of the heating resistor. Finally, with each heating element, which is preferably formed axially along the crucible with a constant cross-section, a constant resistance per length is provided. Advantageously, it is therefore possible to produce constant heating power in the axial direction of the crucible.

According to a preferred variant of the first embodiment of the invention, the heating device has an upper ring-shaped conductor, to which the heating elements (or: heating conductors) are connected in parallel. The upper ring-shaped conductor generally comprises an electrical conductor, which surrounds the crucible at an upper end, i.e. at the end with the crucible opening. All heating elements are connected by a first (upper) end to the upper ring-shaped conductor.

The arrangement of the upper ring-shaped conductor at the crucible opening means that the upper ring-shaped conductor surrounds the crucible opening azimuthally with a radial distance. Alternatively the upper ring-shaped conductor can be arranged with an axial distance in front of the crucible opening. However, to avoid deposition of evaporant on the upper ring-shaped conductor, the latter is preferably arranged outside of the evaporation characteristic of the crucible. According to another alternative, the upper ring-shaped conductor can surround the side wall of the crucible with a distance behind the crucible opening, opposite to the direction of evaporation. This is possible particularly when there is little risk of deposition of evaporant on the crucible opening. No particular requirements are imposed on the shape of the ring-shaped conductor. It can for example have the same shape as the cross-sectional shape of the crucible (e.g. circular, elliptical) or alternatively can have a different shape with straight or curved conductor segments (e.g. polygonal).

It is intended that a first potential should be applied to the upper ring-shaped conductor. The upper ring-shaped conductor is preferably connected to the negative pole of the power supply device, in particular to the negative pole of the power source for resistance heating and of the high-voltage source for electron beam heating.

According to another preferred variant of the first embodiment of the invention, the heating device has a lower ring-shaped conductor, to which the heating elements are connected in parallel. The second (lower) ends of the heating elements are connected to the lower ring-shaped conductor. The lower ring-shaped conductor is provided to be admitted with a second potential. The lower ring-shaped conductor generally comprises an electrical conductor, which surrounds the crucible at a lower end, i.e. at the end with the crucible bottom. The lower ring-shaped conductor preferably has the same axial position as the crucible bottom. Alternatively it can be arranged with an axial distance below the crucible bottom, and then surrounds a holding device of the crucible. In this case reliable heating of the entire crucible bottom can be improved. According to another alternative, the lower ring-shaped conductor can be arranged so that it is displaced from the crucible bottom in the direction of evaporation, i.e. towards the evaporation opening, if reduced requirements are imposed on the heating of the crucible bottom.

According to the invention, the upper ring-shaped conductor or the lower ring-shaped conductor can be adapted to provide the common potential for the upper or lower ends of the heating elements. In this case the other ends of the heating elements, i.e. the lower or the upper ends of the heating elements are not connected to a common conductor, but via separate conductors to one pole of the power and high-voltage sources. Provision of only one of the upper and lower ring-shaped conductors may be advantageous, depending on the actual design of the evaporator cell.

However, a variant of the first embodiment of the invention, in which the upper ring-shaped conductor and the lower ring-shaped conductor are provided, with the heating elements extending between them, is particularly preferred. Advantageously, a particularly stable arrangement of the heating elements is achieved in this way. Through provision of the common potential for the heating elements and the mounting of the heating elements, the ring-shaped conductors perform a dual, mechanical and electrical, function.

According to a second embodiment of the invention, the heating zones can be in contact with one another in the circumferential direction of the crucible. The heating zones are connected to a planar resistance material, which surrounds the crucible partially or in all radial directions. The heating zones preferably form a resistance sleeve (heating foil), which surrounds the crucible radially in all directions. The resistance sleeve can for example be cylindrical or cone-shaped.

With a conical shape of the resistance sleeve, advantageously a front or rear part of the crucible can be heated preferentially. With constant current through the sleeve and with constant thickness of the sleeve material (e.g. 10 μm), the sleeve is heated to the greatest extent on its smallest cross-section. This property of the sleeve is a substantial advantage, as this temperature variation cannot be achieved with individual filaments of constant cross-section.

In the second embodiment of the invention, the heating zones form a single, two-dimensional heating conductor surrounding the crucible. The second embodiment of the invention has the particular advantage that the planar resistance material has increased stability, compared with the individual heating elements spaced apart (first embodiment presented above). The increased stability leads to improved homogeneity in heating the crucible, particularly in electron beam heating.

According to a preferred variant of the second embodiment of the invention, the planar resistance material, in particular the resistance sleeve, has a constant thickness in the axial direction of the crucible. This variant is of advantage particularly when using a cone-shaped resistance sleeve. The conical resistance sleeve has a cross-sectional dimension that decreases from the crucible opening to the crucible bottom. Because the thickness of the resistance material is constant in the axial and azimuthal direction, the integrated cross-section of the resistance sleeve decreases from the crucible opening to the crucible bottom. There is thus an increasing electrical resistance from the crucible opening to the crucible bottom (resistance gradient). Therefore a gradient of heating power can be produced in the axial direction of the crucible from the crucible opening to the crucible bottom.

According to another advantageous feature of the invention, the resistance sleeve has, at its top edge, which surrounds the crucible opening, and/or at its bottom edge, which surrounds the crucible bottom, strips that are curved or bent outwards in the radial direction, which are provided for securing the resistance sleeve correspondingly in each case on an upper and/or lower ring-shaped conductor and for compensating thermal changes in the length of the resistance sleeve.

Typically, owing to radiant emission the crucible has a greater heat loss at the crucible opening, than at the crucible bottom. With constant heating power, this leads to a temperature gradient, which may be undesirable, depending on the actual application, in particular depending on the evaporated product. The formation of a gradient of the heating power can be utilized advantageously, to compensate the temperature gradient or adjust it in a predetermined manner.

The aforesaid resistance gradient is particularly advantageous in electron beam heating. When there is a negative potential at the upper end of the resistance sleeve near the crucible opening, injected electrons experience the electrical resistance on the one hand of the vacuum section to the crucible and on the other hand of the current path through the resistance sleeve. With the resistance gradient, the ratio of the two resistance values can vary in the axial direction of the crucible. Near the crucible opening there is stronger electron beam heating than near the crucible bottom, so that the temperature gradient can be adjusted to compensate the radiation losses at the top of the crucible.

According to a particularly preferred variant of the second embodiment of the invention, the heating zones form a metal foil, which extends between terminals of the heating resistor, which are arranged spaced apart in the axial direction of the crucible, on its outside surface. The metal foil preferably has a thickness in the range from 5 μm to 50 μm, in particular 15 μm to 50 μm or preferably 5 μm to 30 μm, e.g. 5 μm to 8 μm.

According to another variant of the second embodiment of the invention, the upper ring-shaped conductor and/or the lower ring-shaped conductor, which were described above in connection with the first embodiment of the invention, can also be provided on the resistance sleeve. The upper ring-shaped conductor and/or the lower ring-shaped conductor can be secured, e.g. welded, for example to the ends of the resistance sleeve on its outside surface or on its lateral edge.

According to the invention, heating zones that comprise separate heating elements, and heating zones that are connected to a planar resistance material and partially surround the crucible, can be combined. In this case there may be advantages for the provision of a particular distribution of the heating power on the crucible.

As the parallel connection of the heating zones facilitates their support on the crucible, according to another variant of the invention it can be provided that the heating resistor is connected firmly to the crucible via an electrical insulator. The electrical insulator, which comprises a plurality of insulator elements or preferably one single insulator ring, is arranged on an outside surface of the crucible preferably in a sub-region in which the temperature is lower than in other regions of the crucible.

When the lower ring-shaped conductor is provided (first embodiment presented above), this is preferably arranged on the electrical insulator that is connected firmly to the crucible, in particular to the crucible bottom. The combination of the electrical insulator with the lower ring-shaped conductor forms a reliable mounting of the heating elements. When the planar resistance material is provided (second embodiment presented above), its bottom edge is secured to the electrical insulator.

Advantageously, the thermal loading of the electrical insulator can be reduced further if it is secured to a holding device of the crucible, i.e. relative to the axial reference direction of the crucible beneath the crucible bottom. The lower ring-shaped conductor or the bottom edge of the planar resistance material is in this case connected to the electrical insulator via a ring holder. The ring holder bridges the distance between the heating resistor on the crucible bottom and the position of the electrical insulator on the holding device.

The ring holder can form a mechanical carrier of the heating resistor. In this case it consists of an electrically insulating material. Alternatively the ring holder can form an electrical conductor for applying the second potential to the heating resistor. In this case the ring holder consists of an electrically conducting material, and the integrated material cross-section of the ring holder preferably differs from the diameter of the heating elements or the thickness of the resistance sleeve to such an extent that during resistance heating there is low electrical resistance and therefore practically no heating, and during electron beam heating there is practically no electron emission. The ring holder can comprise e.g. a ring of metal foil or sheet, locating pins or stamped or milled parts.

Provision of the electrical insulator on the holding device has the advantage that the holding device is not only excluded from indirect heating, but can even be actively cooled directly, so that undesirable thermal loading of the electrical insulator is excluded.

According to another advantageous variant of the invention, the evaporator cell has a shielding device with a shielding wall, which surrounds the crucible in the radial direction. The shielding wall can advantageously perform several functions. First, thermal shielding of the surroundings of the evaporator cell can be provided, which is advantageous in particular for independent control of several adjacent evaporator cells in a coating installation. Secondly, the shielding wall can form a mechanical carrier for the heating device, in particular of the heating zones and optionally one of the ring-shaped conductors.

A particular advantage of the invention arises from the fact that one end of the heating zones, preferably the upper end, i.e. in the vicinity of the crucible opening, can be connected electrically to the shielding wall. In contrast to the conventional evaporator cell, an electrical insulator is not necessary in the upper region of the crucible, in particular in the vicinity of the crucible opening. Electrical connection of the upper ends of the heating zones (optionally with the upper ring-shaped conductor) to one pole of the power source or high-voltage source can be made via the shielding wall. The heating zones (optionally the upper ring-shaped conductor or the top edge of the planar resistance material) can be secured directly to the shielding wall. This greatly simplifies the construction of the evaporator cell according to the invention.

According to another advantageous variant of the invention, the heating zones can be arranged so that the radial distance of the upper ends of the heating zones from the crucible, in particular from the crucible opening, is greater than the radial distance of the lower ends of the heating zones from the crucible, in particular from the crucible bottom. The radial distance of the upper ends of the heating zones from the crucible opening is preferably selected in the range from 1 mm to 6 mm. The radial distance of the lower ends of the heating zones from the crucible bottom is preferably selected in the range from 1 mm to 4 mm.

With heating zones that extend in a straight line in the longitudinal direction, there is a distance gradient from the crucible opening towards the crucible bottom. Owing to the decreasing radial distance, the resistance of the vacuum section decreases from the heating zones to the side wall of the crucible. Therefore, advantageously, the aforementioned ratio of the resistance values across the vacuum section and through the heating zones can be influenced additionally, to compensate or adjust the temperature gradient in the axial direction and/or to influence the temperature-emission control.

Alternatively, it can be provided that the heating resistor has a smaller radial distance from the side wall at the crucible opening than at the crucible bottom. Advantageously, in this way the heating power near the crucible bottom can be increased compared with the heating power near the crucible opening.

Alternatively or additionally to the distance gradient, according to another advantageous variant of the invention, a resistance gradient can be provided, with which the ohmic resistance of the heating zones is lower at the crucible opening than at the crucible bottom. The resistance gradient can, for example in the second embodiment of the invention as described above, be obtained by the conical shape of the heating resistor or alternatively by a thickness gradient of the heating zones.

According to another alternative of a resistance gradient, it can be provided that the heating resistor has a larger resistance value at the crucible opening than at the crucible bottom. Advantageously, this offers another possibility for setting, if necessary, a higher heating power near the crucible bottom than the heating power near the crucible opening.

In a particularly preferred variant of the invention, the heating zones, in particular the heating elements between the upper ring-shaped conductor and the lower ring-shaped conductor or the planar resistance material, extend in self-supporting fashion. In this case the lower ring-shaped conductor or the bottom edge of the planar resistance material can be secured directly or via the aforementioned locating pins on the electrical insulator, which is arranged at the crucible bottom or the holding device, whereas the upper ring-shaped conductor or the top edge of the planar resistance material can be secured in the vicinity of the crucible opening on the inside surface of the shielding wall. In a cylindrical design with a crucible in the form of a right cylinder and a shielding wall in the form of a straight, cylindrical sleeve, the aforementioned distance gradient is therefore achieved with the radial distance of the heating elements from the crucible increasing in the direction of evaporation.

According to another advantageous variant of the invention, the evaporator cell is equipped with at least one temperature measuring device, with which an operating temperature of the evaporator cell can be detected. This offers in particular the advantage that temperature measurement can be set up simply for different measurement principles. Preferably the temperature measuring device comprises a thermocouple, a bolometer element and/or a pyrometer element. The thermocouple has the advantage of direct and inexpensive temperature measurement, whereas optical temperature measurement with pyrometer or bolometer elements has advantages with respect to contactless measurement over relatively large measuring distances.

However, the thermocouple is preferred for temperature measurement, because it can be calibrated easily and takes up little space. Thermocouples, in particular based on tungsten and rhenium, are available in the high-temperature range of interest (see e.g. R. R. Asamoto et al. in “The Review of Scientific Instruments”, Vol. 38, 1967, p. 1047). For optical temperature measurement, preferably a radiation detector is provided outside of the evaporator cell, with which, optionally through an inspection window or an opening in a shielding device, temperature-dependent thermal radiation emanating from the outside or inside wall of the crucible can be detected.

When, according to another variant of the invention, the thermocouple with an axial distance below the crucible bottom, can be displaced in the axial reference direction of the crucible, several advantages can be achieved. First, with a simple displacement, the axial distance of the thermocouple from the crucible bottom can be adjusted and can thus be adapted to the actual operating conditions of the evaporator cell. Moreover, e.g. for purposes of maintenance or replacement, the thermocouple can easily be removed from the evaporator cell, without the need for complicated dismantling. For this purpose, the thermocouple preferably has a straight shape. This makes it possible to move the thermocouple forward through a straight channel through the holding device of the crucible and optionally other components of the evaporator cell to the desired position underneath the crucible bottom. The optimum axial distance from the crucible bottom can be determined for example in series of tests or with a prior calibration measurement.

According to another advantageous feature of the invention, the holding device of the evaporator cell is adapted for the thermally insulated positioning of the crucible relative to the other parts of the evaporator cell and in particular relative to a carrier. The holding device represents a mechanical holder, which largely leaves the outside surface of the crucible free, when the latter is formed from an electrically conducting material. Preferably the holding device is in this case provided on the crucible bottom, so that for heat transfer from the heating device, the side walls of the crucible are largely exposed. If the holding device consists of an electrically conducting material, advantageously in addition to mechanical holding, it can serve simultaneously as high-voltage contact for the crucible. If the crucible consists of an electrically non-conducting material, the holding device is formed in such a way that it covers most of the outside surface of the crucible. In this case, preferably a positive connection is provided between the outside surface of the crucible and the inside surface of the holding device.

When the holding device is formed by a component with a hollow profile, there may be advantages for reduction of heat conduction from the crucible to the surroundings and for stable positioning of the crucible even at extremely high temperatures. The holding device is for example a hollow cylinder or a hollow cone, which is fitted to the underside of the crucible. The cylindrical or cone-shaped holding device has particularly high mechanical stability. The crucible is held firmly and all-over, with protection against torsion and warping.

Advantageously, the hollow profile, which forms the high-voltage contact of the crucible, creates a space in the immediate vicinity of the crucible, in which the operating temperature of the crucible can be measured and in which there is a reduced field strength. Therefore the temperature measuring device is preferably provided for temperature measurement inside the holding device. The holding device has for example an axial opening, through which the thermocouple can be introduced into the holding device. Positioning of the thermocouple in the hollow profile of the holding device has the particular advantage that it achieves all-round shielding of the thermocouple in particular against the high field strengths during operation of the heating device as electron beam heating, and undesirable high-voltage arcing is avoided.

Preferably, a receptacle is provided on the carrier, in which the holding device can be inserted. The receptacle has for example the form of a cylindrical or cone-shaped tray, the internal shape of which matches the external shape of the hollow profile of the holding device. Advantageously the inserted holding device forms a solid mechanical contact with the carrier, so that tilting of the crucible during operation of the evaporator cell is avoided.

Advantageously, the evaporator cell according to the invention makes accurate temperature setting in the crucible possible. For this purpose, preferably a control device is provided, with which the heating device can be set. The control device can contain the following control circuits. A first control circuit serves for setting a heating current of the heating resistor for operation as resistance heating. The second control circuit serves for setting an electron current from the heating resistor to the crucible for operation as electron beam heating.

In the control circuits, the heating and/or electron current of the heating resistor is generally controlled using an actual quantity, which is selected depending on the actual task of the evaporator cell. For example, a measured vapor deposition rate can be used as the actual quantity for the control circuits. Preferably, control takes place in relation to the operating temperature of the crucible. For this purpose, the temperature measuring device is connected to at least one of the control circuits.

Further advantages are achieved with an embodiment of the invention in which the control device has one single control circuit, with which the temperature of the evaporator cell can be set. Particularly preferably, the single control circuit is intended for voltage regulation of the heating device. With the control circuit, the voltage at the ends of the parallel-connected heating elements is set according to an actual quantity, e.g. the temperature that was determined with the temperature measuring device. Advantageously, the evaporator cell is controlled exclusively via the heating voltage of the parallel connection of the heating elements.

The inventors found that as a result of parallel connection of the heating elements, at a sufficiently high heating voltage, preferably in the range from 2 V to 8 V, e.g. at 4 V, the transition from resistance heating to electron beam heating takes place automatically, with the electron beam heating power following the heating voltage passively and with high stability. In contrast to control of the conventional evaporator cell, it is not necessary to control the high-voltage source. It was found that with control of the heating voltage of the heating elements, the high-voltage source is controlled automatically. Surprisingly, with the one control circuit, even with simultaneous operation of resistance and electron beam heating, a stable rather than oscillating control characteristic was observed.

The preferred control characteristic of the electron beam heating is characterized by a temperature-emission control, in which the resistance of the vacuum section to the crucible steadily decreases with increasing temperature of the heating zones. The electron current over the vacuum section increases continuously with increasing temperature of the heating zones. In contrast, with a field-emission control there would be a sudden increase in electron current. Temperature-emission control is achieved with an accelerating voltage, for which at the given length of the vacuum section, field-emission is excluded (e.g. U<500 V), and a sufficiently high electron current, at which temperature-emission occurs (e.g. I=1 A to 3 A), of the electron beam heating.

It was found to be particularly advantageous if the crucible and the heating resistor of the evaporator cell according to the invention, and preferably also the shielding wall of the shielding device, consist of tantalum entirely. Although tantalum oxide has a relatively low melting point and a relatively high vapor pressure, the inventors found, surprisingly, that even in high-temperature operation of the evaporator cell, no undesirable tantalum was found in films that were produced with the evaporator cell.

A coating installation, which is equipped with at least one evaporator cell according to the invention, constitutes an independent subject of the invention. In contrast to conventional electron beam evaporators, in which flat crucibles are typically provided, the evaporator cell in the coating installation can be arranged with a crucible aligned obliquely relative to the vertical or even horizontally.

Further details and advantages of the invention are explained below, referring to the appended drawings, showing:

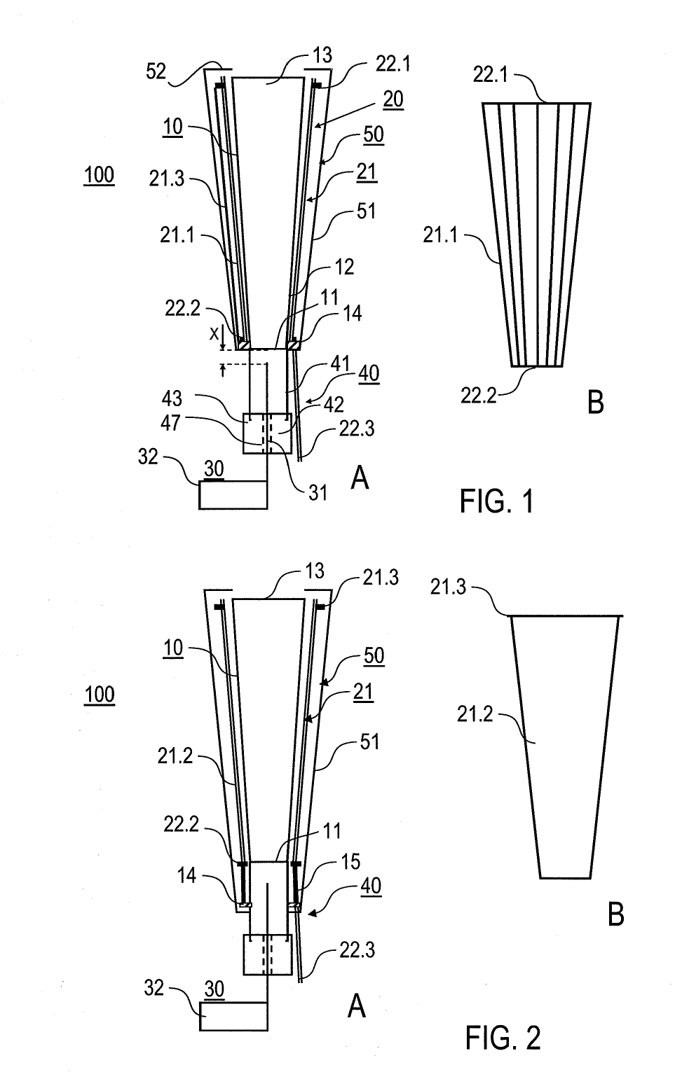

FIGS. 1A and 1B: schematic views of the first embodiment of the evaporator cell according to the invention;

FIGS. 2A and 2B: schematic views of the second embodiment of the evaporator cell according to the invention;

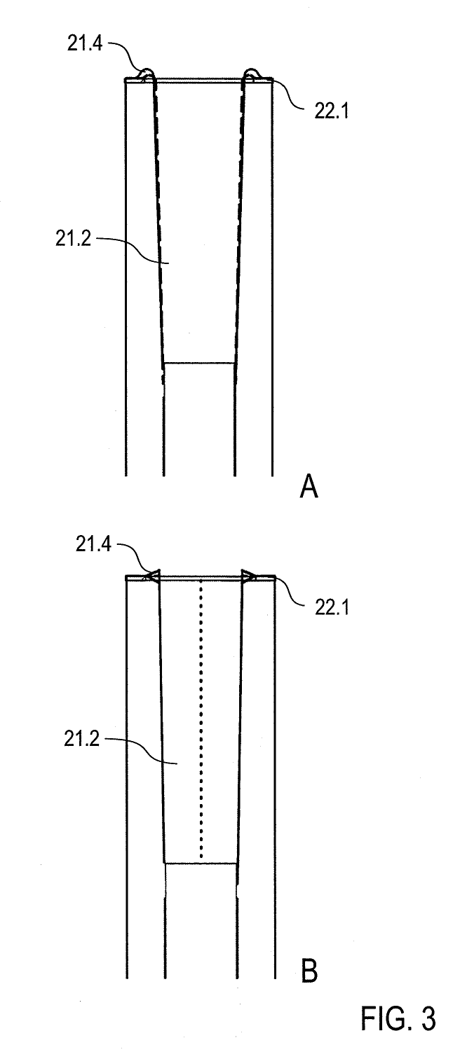

FIGS. 3A and 3B: schematic views of further variants of the second embodiment of the evaporator cell according to the invention;

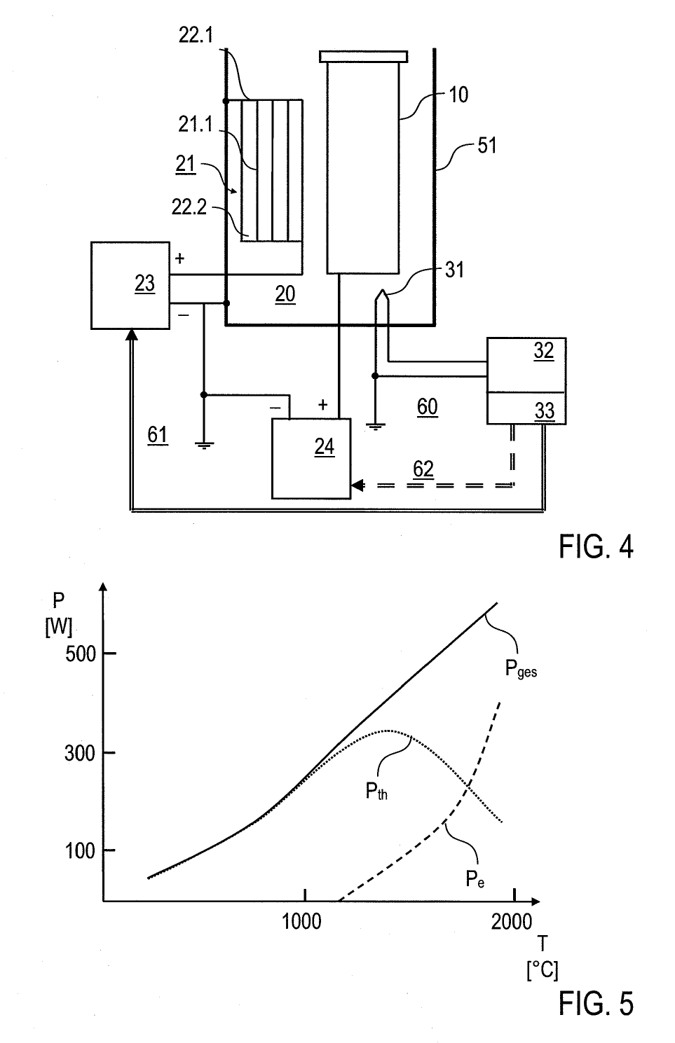

FIG. 4: the combination of evaporator cell with a control device according to the invention;

FIG. 5: curves illustrating various operating states of the evaporator cell according to the invention; and

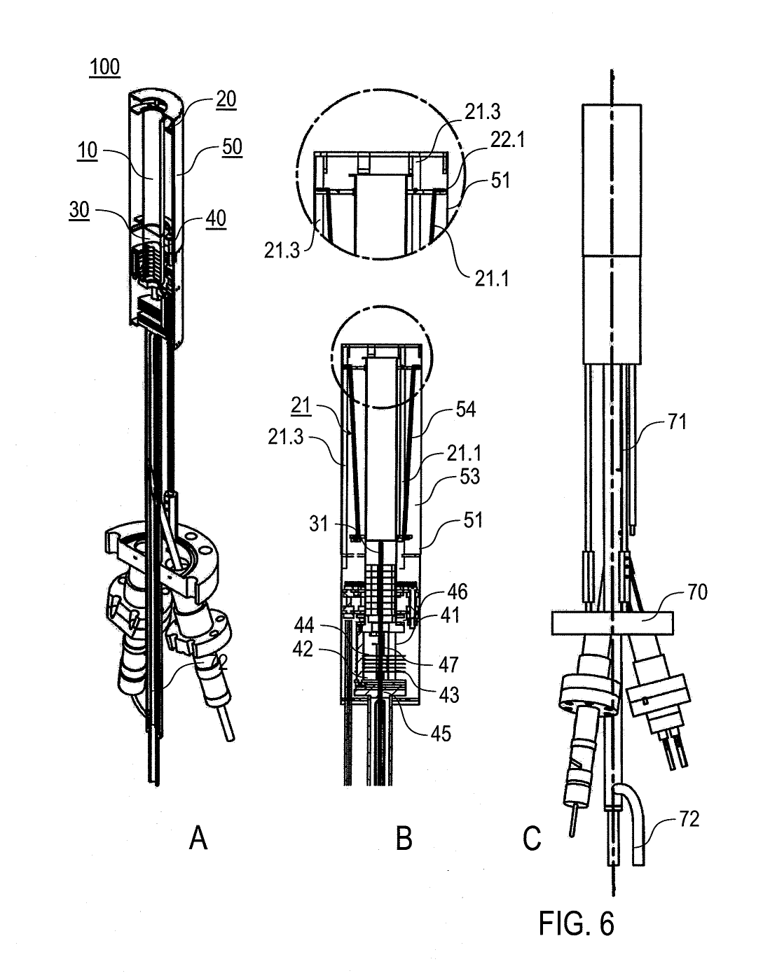

FIGS. 6A to 6C: details of another embodiment of an evaporator cell according to the invention.

The first embodiment of the evaporator cell according to the invention 100 shown in FIG. 1A as a schematic sectional view comprises a crucible 10, a heating resistor 21 of a heating device 20, a temperature measuring device 30, a holding device 40 and a shielding device 50. The heating resistor 21 comprises parallel-connected heating zones, which are formed by heating elements 21.1 running separately.

The crucible 10 for receiving evaporant with a crucible bottom 11, an encircling side wall 12 and an outlet 13 is of conical shape with a diameter increasing from the crucible bottom 11 to the outlet 13. The crucible 10 consists of a single-layer or multi-layer material, which is dimensionally stable and mechanically stable up to a temperature of 3000° C. The crucible 10 can consist of metal sheet completely or of a composite with a non-electrically conducting main body and a metallic coating, and for evaporator operation the electrically conducting part of the crucible 10 is in each case connected to a high-voltage source 24 (see FIG. 4). The crucible 10 consists for example completely of tantalum or of a tantalum-tungsten combination or a tungsten-rhenium alloy. The tungsten-tantalum combination comprises for example a structure with the crucible bottom 11 made of tungsten and the side wall 12 made of tantalum or a two-layer structure with an inner tungsten cone and an outer tantalum cone. This last-mentioned variant has the advantage that the outer sheet of tantalum provides mechanical stability for the inner tungsten cone. The dimensions of the crucible 10 are, for an internal volume of approx. 10 cm³ for example: diameter of the crucible bottom: 1 cm, axial length of the crucible 10: approx. 10 to 15 cm, diameter of the outlet 13: approx. 1.5 cm.

The temperature measuring device 30 comprises a thermocouple 31, whose contact point is arranged below of the crucible bottom 11 and is connected to a measuring transducer 32. The thermocouple is for example a tungsten-rhenium thermocouple, as described in the work of R. R. Asamoto et al. cited above. The measuring transducer 32 is for example of the “Eurotherm 2604” type.

The holding device 40 comprises a hollow cylinder 41 made of a temperature-resistant material, e.g. tantalum with a channel 47 running axially. Through channel 47, the thermocouple 31 can be passed, electrically insulated, through the interior of the hollow cylinder 41. The thermocouple 31 is movable in channel 44, so that the axial distance X from the crucible bottom can be adjusted. The axial distance X is set for example in the range from 2 mm to 15 mm.

The bottom edge of the hollow cylinder 41 is connected to a carrier 42, which is arranged, stationary or adjustable, in a coating installation. The carrier 42 contains an annular receptacle 43, in which the bottom edge of the hollow cylinder 41 is secured. The holding device 40 serves for stable holding and as high-voltage electrical contact of the crucible 10.

The holding device 40 constitutes thermal insulation between the crucible 10 and the other parts of the coating installation. To minimize heat conduction, the hollow cylinder 41 consists of sheet metal with a thickness less than 500 μm, preferably less than 200 μm, e.g. in the range from 50 μm to 200 μm.

The shielding device 50 comprises a laterally encircling shielding wall 51 and a shielding cap 52. The shielding wall 51 constitutes a thermal barrier outwards and a mechanical holder for the upper ring-shaped conductor 22.1 of the heating device 20. It consists e.g. of Ta sheet with a thickness of 50 μm or several layers of Ta foil. The shielding cap 52 serves for thermal insulation between the evaporator cell 100 and a substrate to be coated. The shielding cap 52 shields the distance between the crucible 10 and the shielding wall 51, in which the heating elements 21.1 are arranged, towards the substrate. At the centre of the shielding cap 52 there is an opening, which allows the stream of vapor to pass from the crucible 10 to the substrate. The opening is selected as small as possible depending on the application (e.g. 15 mm), to improve the uniformity of temperature distribution in the crucible 10 and to minimize the required heating power.

The heating elements 21.1 of the heating device 20, which form the heating resistor 21, are separate heating conductors, which extend between an upper ring-shaped conductor 22.1 and a lower ring-shaped conductor 22.2 (see schematic side view in FIG. 1B). In addition, a connecting lead 22.3 is provided, which is connected to the heating current source 23 (see FIG. 4). The heating elements 21.1 extend in self-supporting fashion between the upper and lower ring-shaped conductors 22.1, 22.2. Each of the heating elements 21.1 consists of a straight resistance wire, which is manufactured from a material usually employed for resistance heating, e.g. tungsten or tantalum, with a diameter of e.g. 0.635 mm. The number of heating elements 21.1 is selected for example in the range from 4 to 20, particularly preferably in the range from 6 to 10. The heating elements 21.1 are arranged with uniform azimuthal distribution on the periphery of the crucible 10.

According to a modified variant of the invention, the heating elements can be formed by curved resistance wires. In this case all resistance wires have the same curvature, so that the heating elements can be connected in parallel with a certain mutual distance between the upper and lower ring-shaped conductors 22.1, 22.2. Curved heating elements can for example have a periodic structure, such as a wave-shaped, triangular or spiral structure or a bow-shaped structure extending between the upper and lower ring-shaped conductors 22.1, 22.2.

The heating elements 21.1 are arranged on the outside surface of the side wall 12 with a radial distance from its surface. The radial distance is determined by the dimensions of the upper and lower ring-shaped conductor 22.1, 22.2 and their attachment on the one hand to the shielding device 50 and on the other hand to the crucible 10.

The upper ring-shaped conductor 22.1 is secured, via bars running radially outside of the heating elements 21.1 and inside of the shielding device 50 (see e.g. 21.3), to the insulator 14, to the carrier 42 or some other stationary part of the coating installation 30 (see also FIG. 6). Several bars 21.3 (e.g. three) are provided, which are arranged with uniform azimuthal distribution. The bars 21.3 consist for example of tantalum with a cross-section of 2 to 3 mm. The bars 21.3 can touch or make electrical contact with the inside surface of the shielding wall 51, which is for example formed by tantalum.

The shielding device 50 is secured to an electrically insulating part of the carrier 42 or another stationary part of a coating installation (not shown). The shielding wall 51 can rest on the bars 21.3, which form a frame or a framework for the shielding device 50. The shielding device 50 can additionally have an outer cooling plate (not shown), which for example comprises a double jacket cooled with liquid nitrogen or water. As the upper ring-shaped conductor 22.1 is at a distance from the side wall 12 and the crucible opening 13, the crucible 10 is freestanding, secured exclusively on the holding device 40. The upper ring-shaped conductor 22.1 consists for example of a curved wire (torus) of tantalum with a diameter of 2 mm or an annular sheet of tantalum with a thickness of 1 mm.

The lower ring-shaped conductor 22.2 is fastened to an annular insulator 14, which surrounds the crucible 10 at the crucible bottom 11. The insulator 14 is secured to the side wall 12 or an offset sub-region of the shielding wall 51. The attachment is for example formed from boron nitride. The insulator 14 contains a through-hole for receiving the connecting lead 22.3, which is connected to the lower ring-shaped conductor 22.2. The lower ring-shaped conductor 22.2 also consists of tantalum in the form of a curved wire (torus) or annular sheet. The heating elements 21.1 are fastened by a welded joint to the lower ring-shaped conductor 22.2. The insulator 14 consists for example of boron nitride, sapphire or quartz.

The second embodiment of the evaporator cell according to the invention 100 shown in a schematic sectional view in FIG. 2A also comprises the crucible 10, the heating resistor 21 of the heating device 20, the temperature measuring device 30, the holding device 40 and the shielding device 50. These components are essentially constructed as described above with reference to FIG. 1A. An essential difference from the first embodiment relates to connection of the heating zones to a resistance sleeve 21.2.

As shown in the schematic side view in FIG. 2B, the heating zones form a conical resistance sleeve 21.2, whose diameter increases from the crucible bottom 11 to the crucible opening 13. The resistance sleeve 21.2 is for example made from tantalum foil with a thickness less than or equal to 30 μm, e.g. 25 μm or 10 μm. The diameter at the bottom edge of the resistance sleeve 21.2 is selected for example in the range from 1 cm to 2 cm, whereas the diameter at the top edge of the resistance sleeve 21.2 is selected between 2 cm and 3 cm. In the variant shown in FIG. 2, the resistance sleeve 21.2 is fastened to bars as in the first embodiment, with its top edge or with an upper ring-shaped conductor optionally provided on the top edge (not shown in FIG. 2). Modified variants of attachment of the resistance sleeve 21.2 are described below with reference to FIG. 3. The bottom edge of the resistance sleeve 21.2 is provided with a welded-on ring 22.2 and is secured via locating pins 15 and an annular insulator 14 on the holding device 40 with an axial distance underneath the crucible bottom 11.

The locating pins 15, which carry the resistance sleeve 21.2, are secured to the annular insulator 14. For example two or more locating pins 15 are provided, which consist of an electrically insulating material, e.g. boron nitride (in particular pyrolytic boron nitride, PBN) or of an electrically conducting material, e.g. tantalum or tungsten. One of the locating pins 15 can be used as electrical connection of the conical sleeve 21.2 to the connecting lead 22.3.

The combination of the insulator 14 with the locating pins 15 shown in FIG. 2A can also be provided for holding the heating resistor in the first embodiment of the invention (see FIG. 1A).

FIG. 3 shows further variants of the resistance sleeve 21.2, which advantageously permit improved stability of securing of the top edge of the resistance sleeve 21.2. For clarity, the crucible and other parts of the evaporator cell are not shown in FIG. 3. The resistance sleeve 21.2 has, at its upper end in the vicinity of the crucible opening 13, several cuts, which form flexible strips 21.4 along the circumferential direction of the resistance sleeve 21.2. The strips 21.4 consist of the wall material of the resistance sleeve 21.2. For example, 10 to 20 uniformly distributed strips 21.4, with a length of e.g. 1 cm in the axial direction (length of the cuts), are provided at the upper end of the resistance sleeve 21.2 in the circumferential direction. The strips 21.4 are led, e.g. curved or bent, outwards in the radial direction, and are secured to the upper ring-shaped conductor, e.g. are welded to the upper ring-shaped conductor 22.1.

Advantageously, securing the top edge of the resistance sleeve 21.2 via the strips 21.4 improves the compensation of thermal changes in length of the resistance sleeve 21.2. If the length of the resistance sleeve 21.2 when hot increases e.g. by up to two millimeters compared with when it is cold, this change in length can be accommodated by the strips 21.4. In this way an undesirable thermal-mechanical overloading of the resistance sleeve 21.2, e.g. upsetting or distortion, or even detachment thereof from the ring-shaped conductor, is reliably avoided. The ring-shaped conductor can have a larger diameter compared with FIG. 2.

According to FIG. 3A, at its upper end the resistance sleeve 21.2 is not welded all-over to the upper ring-shaped conductor, but via the bow-shaped strips 21.4. As a result the resistance sleeve 21.2 can expand in axial length, without being mechanically overloaded. Mechanical destruction of the resistance sleeve through different thermal expansion relative to the colder outer part of the cell can thus be effectively prevented.

According to FIG. 3B, the strips 21.4 are not made bow-shaped, but are bent with a narrow radius and led radially outwards almost perpendicular to the crucible centre line. In the cold state, the angle viewed from the bottom is greater than 90 degrees, and in the hot state is less than 90 degrees, preferably respectively by the same amount. Both states are illustrated in FIG. 3B. The almost perpendicular radial bracing of the top edge of the sleeve results in a stable lateral guiding of the upper end of the resistance sleeve 21.2, without losing the possibility of slight thermal expansion of the resistance sleeve 21.2. Advantageously, this reliably prevents lateral deviation of the resistance sleeve 21.2 from the axis of symmetry of the cell and short-circuiting with the crucible in the middle (not shown in FIG. 3).

According to another embodiment of the invention, the resistance sleeve 21.2 can have at its lower end, i.e. in the vicinity of the crucible bottom, cuts that form flexible strips in the circumferential direction of the resistance sleeve 21.2, as described above with reference to FIGS. 3A and 3B. The strips are then fastened to the lower ring-shaped conductor 22.2 (see FIG. 2). Moreover, securing can be provided via curved or bent strips on the two axial ends of the resistance sleeve 21.2 (heating foil).

FIG. 4 illustrates schematically the connection of the heating device 20 to the heating current source 23 and the high-voltage source 24. For clarity, in FIG. 3 the upper and lower ring-shaped conductors 22.1, 22.2 and the heating elements 21.1 are shown next to the crucible 10, although in practice they surround the crucible 10. In the second embodiment, the heating elements 21.1 are replaced with the resistance sleeve 21.2.

Adjustment of the operating current of the heating device 20 is effected with a control device 60 shown schematically in FIG. 4. The heating elements 21.1 on the outside surface of the crucible 10 are parallel-connected to the heating current source 23. The heating current source 23 is a controllable DC power supply for a heating current of up to 120 A at an output DC voltage up to 20 V. One (positive) connecting contact of the heating current source 23 is connected to the lower ring-shaped conductor 22.2, whereas the other (negative) connecting contact of the heating current source 23 together with the upper ring-shaped conductor 22.1, the shielding wall 51, the negative connecting contact of the high-voltage source 24 and a terminal of the thermocouple 31 is connected to earth potential. Earthing of the thermocouple 31 is optionally provided. Alternatively the measuring transducer 32 and the controller 33 can be at crucible potential.

The high-voltage source 24 is a DC power supply with an output current e.g. up to 10 A and an output voltage e.g. up to 500 V. For reasons of cost and owing to simplified operation in the low-voltage range, preferably a high-voltage source 24 with an output voltage of less than or equal to 300 V is used. The positive connecting contact of the high-voltage source 24 is connected via the holding device 40 (see FIG. 1 or 2) to the crucible 10, which in electron beam operation of the heating device 20 represents the anode, onto which electrons are accelerated by the heating elements 21.1. According to modified variants of the invention, the high-voltage source can be adapted for lower (for example up to approx. 50 V) or higher voltages (for example up to approx. 5000 V). In practice, lower voltages correspondingly with currents as high as possible are preferred, in order to avoid unintentional electric arcing and to obtain a soft control characteristic of the electron beam heating (temperature-emission control).

The measuring transducer 32 of the thermocouple 31 is connected to a controller 33 (for example a PID controller). Depending on the design of the control device 60, the controller 33 has one or two outputs, from which control signals are supplied to the heating current source 23 and optionally to the high-voltage source 24.

Preferably the control device 60 comprises one single control circuit 61. In control circuit 61, the output voltage of the heating current source 23, which is applied to the upper and lower ring-shaped conductors 22.1, 22.2, is controlled according to the operating temperature of the crucible 10. Alternatively, as in the conventional evaporator cell, two control circuits 61, 62 can be provided (see dashed arrow from 33 to 24). In the optionally provided control circuit 62, the electron current from the heating elements 21.1 to the crucible 10 is also controlled as a function of the operating temperature of the crucible 10.

For temperature setting, for example the characteristic curve shown in FIG. 5 is realized. In a first operating phase, first a heating voltage is applied to the heating elements 21.1, so that a heating current flows through the heating elements 21.1. The heating power Pₜₕ and therefore the temperature of crucible 10 are controlled exclusively via the heating voltage. With the control device 33, according to FIG. 5, first the temperature in the crucible is raised with the thermal heating (dashed, power Pₜₕ), until a temperature is reached at which electron emission from the heating resistor 21 is initiated. When, as a result of resistance heating, a sufficiently high temperature of e.g. 1000° C. to 1500° C. has been reached, in a further operating phase electron beam heating is initiated. Electron emission from the heating elements 21.1 to the crucible 10 is for example already initiated at a high voltage of 300 V. The electron beam heating (dashed, power Pₑ) is superposed on the heating. The two components add to give the power Pₜₒₜ (drawn with a solid line). To raise the temperature further, the power Pₜₕ of the resistance heating is not increased, instead the electron beam heating is used. The resistance heating is reduced. According to the invention, at a crucible temperature above 2200° C. the resistance heating can even be switched off, as the heating elements are heated by the crucible. With an increase in the electron current e.g. to 1 A at a voltage of 2000 V over the vacuum section between the heating elements and the crucible, a temperature of 2700° C. is reached.

In order to achieve the smoothest possible transition of temperature adjustment on changing from resistance to electron beam heating, the high voltage of the high-voltage source 24 is already applied to the crucible 10 during the first operating phase of resistance heating.

Details of another embodiment of the evaporator cell 100 are shown in FIGS. 6A (perspective sectional view), 6B (enlarged partial view) and 6C (side view). The essential difference between the embodiments in FIGS. 1 (or 2) and 6 consists of the geometric shape of the crucible 10. Otherwise the details shown in FIG. 6 can also be realized with the embodiments of the invention shown in FIG. 1, 2 or 3.

FIGS. 6A and 6B show details of the crucible 10, the heating resistor 21, the temperature measuring device 30, the holding device 40 and the shielding device 50. The crucible 10 is a hollow right cylinder of tungsten sheet. The shielding wall 51 consists of several layers of tantalum foil. The heating elements 21.1 of the heating resistor 21 extend over the entire length of the crucible 10. Advantageously, in electron beam heating, electron emission also takes place along the full length of the heating elements 21.1.

FIGS. 6A and 6B show, for example, a conical shape of the heating resistor 21, the diameter of which increases in the axial direction towards the crucible opening. Alternatively the heating resistor 21 can be of cylindrical shape with a constant radial distance of the heating elements 21.1 from the cylindrical crucible 10 or can be of a conical shape, with diameter decreasing in the axial direction towards the crucible opening.

Mechanical mounting of the heating elements 21.1 and of the upper ring-shaped conductor 22.1 is effected with the bars 21.3, which are arranged on the inside surface of the shielding wall 51.

The hollow cylinder 41 of the holding device 40 is tapered at its lower end in the shape of a cone. The cone-shaped taper is inserted in a receptacle 43, also cone-shaped, of the carrier 42. The hollow cylinder 41 is fixed in the holder 43 with an internal piece 44, also cone-shaped, which can be drawn with a straining screw 45 into the receptacle 43 of the carrier 42. The straining screw 45 is hollow internally, so that the channel 47 is formed, for passing the thermocouple 31 axially into the internal space of the hollow cylinder 41. On the upper side of the carrier 42, several layers of tantalum sheet 46 are arranged, in order to improve the thermal insulation between the crucible 10 and the carrier 42.

The carrier 42 is connected to a base 70 via rigid tubes 71, in which the connecting leads of the heating resistor, the high-voltage cable of the crucible and the leads of the thermocouple are arranged. The tubes 71 also serve for cooling the connecting leads and the holding device 40 with cooling water, which is supplied via cooling water connections 72 (see FIG. 6C). The base 70 has a vacuum flange (e.g. of size CF 40), which can be mounted on a coating installation.

The features of the invention disclosed in the above description, the drawings and the claims may be of importance both individually and in combination for implementation of the invention in its various embodiments.

1. An evaporator cell, which is adapted for evaporation of an evaporant, comprising:
a crucible for accommodating the evaporant, which has a crucible bottom, a side wall, which extends in an axial direction of the crucible, and a crucible opening, and
a heating device with a heating resistor, which comprises a plurality of heating zones, which are arranged on an outside surface of the crucible and extend axially along the crucible, wherein
the heating zones are adapted for at least one of multilateral resistance heating and multilateral electron beam heating of the crucible, and
the heating zones are formed in such a way that a heating current flows in parallel and in a same direction through the heating resistor through all heating zones.

2. The evaporator cell according to claim 1, wherein the heating zones comprise separate heating elements, which are connected in parallel.

3. The evaporator cell according to claim 2, wherein the heating device has an upper ring-shaped conductor, which surrounds the crucible at the crucible opening and to which the heating elements are connected in parallel.

4. The evaporator cell according to claim 2, wherein the heating device has a lower ring-shaped conductor, which surrounds the crucible at the crucible bottom and to which the heating elements are connected in parallel.

5. The evaporator cell according to claim 4, wherein the lower ring-shaped conductor is connected to the electrical insulator.

6. The evaporator cell according to claim 1, wherein the heating zones are connected as a planar resistance material, which forms a resistance sleeve.

7. The evaporator cell according to claim 6, wherein the resistance sleeve has, on at least one of a top edge, which surrounds the crucible at the crucible opening, and a bottom edge, which surrounds the crucible at the crucible bottom, strips curved outwards in a radial direction, which are provided for securing the resistance sleeve.

8. The evaporator cell according to claim 6, wherein:
the heating zones have a constant thickness along the axial direction of the crucible, or
the heating zones comprise a metal foil.

9. The evaporator cell according to claim 1, wherein the heating resistor is connected via an electrical insulator to the crucible or a holding device of the crucible.

10. The evaporator cell according to claim 9, wherein the heating resistor is connected via the electrical insulator to the crucible bottom.

11. The evaporator cell according to claim 1, wherein:
a shielding device is provided, which has a shielding wall, which surrounds the crucible radially, wherein
the heating resistor is connected electrically to the shielding wall at the crucible opening.

12. The evaporator cell according to claim 11, wherein the heating resistor is secured on the shielding wall.

13. The evaporator cell according to claim 1, wherein the heating resistor has a larger radial distance from the side wall at the crucible opening than at the crucible bottom.

14. The evaporator cell according to claim 1, wherein the heating resistor has a smaller radial distance from the side wall at the crucible opening than at the crucible bottom.

15. The evaporator cell according to claim 1, wherein the heating resistor has a smaller resistance value at the crucible opening than at the crucible bottom.

16. The evaporator cell according to claim 1, wherein the heating resistor has a larger resistance value at the crucible opening than at the crucible bottom.

17. The evaporator cell according to claim 1, wherein a temperature measuring device is provided, with which an operating temperature of the evaporator cell can be measured and which comprises at least one of a thermocouple, a bolometer element and a pyrometer element.

18. The evaporator cell according to claim 17, wherein the thermocouple comprises a straight component, which extends axially along the crucible and is arranged on an underside of the crucible bottom movable axially along the crucible.

19. The evaporator cell according to claim 1, wherein a control device is provided for adjusting the heating device.

20. The evaporator cell according to claim 19, wherein the control device has a first control circuit for setting resistance heating and a second control circuit for setting electron beam heating.

21. The evaporator cell according to claim 19, wherein the control device has one single control circuit, with which resistance heating can be set in a lower temperature range and electron beam heating can be set in an upper temperature range.

22. The evaporator cell according to claim 21, wherein the control circuit is adapted for voltage regulation of the heating device.

23. The evaporator cell according to claim 21, wherein the control circuit is adapted for temperature-emission control of the electron beam heating.

24. The evaporator cell according to claim 1, wherein the crucible and the heating resistor consist of tantalum.

25. The evaporator cell according to claim 24, wherein the shielding wall consists of tantalum.

26. A method of evaporation of an evaporant with an evaporator cell according to claim 1, comprising the steps of:
heating of the evaporant in the crucible in a lower temperature range with resistance heating, and
heating of the evaporant in the crucible in an upper temperature range with electron beam heating.

27. The method according to claim 26, further comprising the step of setting of the heating device with a control device.

28. The method according to claim 27, wherein operation as resistance heating is set with a first control circuit of the control device and operation as electron beam heating is set with a second control circuit of the control device.

29. The method according to claim 27, wherein resistance heating operation and electron beam heating operation are set with one single control circuit of the control device.

30. The method according to claim 29, wherein voltage regulation of the heating device is provided with the single control circuit.

31. The method according to claim 29, wherein temperature-emission control of the electron beam heating is provided.

32. The method according to claim 26, wherein the evaporant contains an oxide of a rare-earth element, which is evaporated from a crucible, which consists of tantalum.

33. A method of using an evaporator cell according to claim 1, comprising the step of providing the evaporator cell as a source of vapor in a coating installation.
